(19) United States
(12) Patent Application Publication
(10) Pub. No.: US 2002/0179314 A1
(43) Pub. Date: Dec. 5, 2002

(54) Housing shield for shielding against electromagnetic radiation

(76) Inventors: Erwin Grave, Heikendorf (DE); Lutz Rebetge, Kiel (DE)

Correspondence Address: Lawrence P. Kessler, Patent Department, NexPress Solutions LLC, 1447 St. Paul Street, Rochester, NY, 14653-7103, US

(21) Appl. No.: 10/151,268

(22) Filed: May 20, 2002

(30) Foreign Application Priority Data
Jun. 1, 2001 (DE) 101 26 889.0

(51) Int. Cl. H05K 9/00

(52) U.S. Cl. 174/35 GC

(57) ABSTRACT

A simple and cost-effective safety against electromagnetic radiation in housings, wherein a housing shield for shielding against electromagnetic radiation for intermediate spaces of a housing including housing parts, has an electrically conducting spiral coiled spring that is arranged on the intermediate spaces to be shielded and extends between the housing parts.

### FIELD OF THE INVENTION

The invention involves a housing shield for shielding against electromagnetic radiation.

### BACKGROUND OF THE INVENTION

In electric and electronic devices, electromagnetic fields occur due to the flow of electric current. Due to the high concentration of electric and electronic devices in modem life such devices can interfere with each other. Further, negative effects of electromagnetic fields on human tissue has been discussed in recent years. The term of electromagnetic compatibility (EMC) was coined, which describes the entirety of all phenomena that result from electric and magnetic perturbing radiation, and legal specifications were issued for the observance of certain perturbing radiation emissions. In order to avoid the electric and magnetic perturbing radiation, device housings are manufactured to be as shielded as possible. Sometimes holes between the parts of the device housing cannot be prevented, however.

The U.S. Pat. No. 4,640,979 describes a radiation-impermeable shield for electronic devices with a spring component that is attached to a flat part of a housing, which ensures the contact between one part and another part. The spring element has a pair of end sections that are connected by a middle section with a convex design and have hook-like sections for the attachment of the spring to the flat section. The U.S. Pat. No. 4,640,979 requires, among other things, a flat housing with bore holes, expensive shaping of the spring, and can only be applied at certain points.

### SUMMARY OF THE INVENTION

Accordingly, the purpose of the invention is to prepare a simple and cost-effective safety shield from electromagnetic radiation in housings. This purpose is achieved with a housing shield for shielding against electromagnetic radiation for intermediate spaces of a housing including housing parts, having an electrically conductive spiral-coiled spring that is arranged on intermediate spaces that are to be shielded and extend between the housing parts. In this process, the spiral-coiled spring can be manufactured in a cost-effective manner and can be mounted on the housing in a simple and cost-effective manner. The spiral-coiled spring can be constructed as a compression spring and be mounted without additional mounting mechanisms by pressure on the housing parts, i.e. held on the housing parts only by spring tension. The housing parts can have projections for mounting the springs in order to ensure a secure mount of the spiral-coiled spring on the housing parts. The spiral-coiled spring can be constructed so that it is flexible. By this characteristic, the spiral-coiled spring can also be used at bends and corners of the housing and adapted to them.

The invention, and its objects and advantages, will become more apparent in the detailed description of the preferred embodiment presented below.

### BRIEF DESCRIPTION OF THE DRAWINGS

In the following, the invention is explained in greater detail using the drawings.

Shown are:

FIG. 1, which is a cross-section through a part of an electronic housing with an electrically conducting spiral-coiled spring electromagnetic radiation shield according to this invention;

FIG. 2, which is a side view of a housing part with projections for mounting the spring electromagnetic radiation shield in an embodiment of this invention; and

FIG. 3, which is an overhead view of an electronic housing without a housing cover with mounted bent spiral coil spring electromagnetic radiation shield according to this invention.

### DETAILED DESCRIPTION OF THE INVENTION

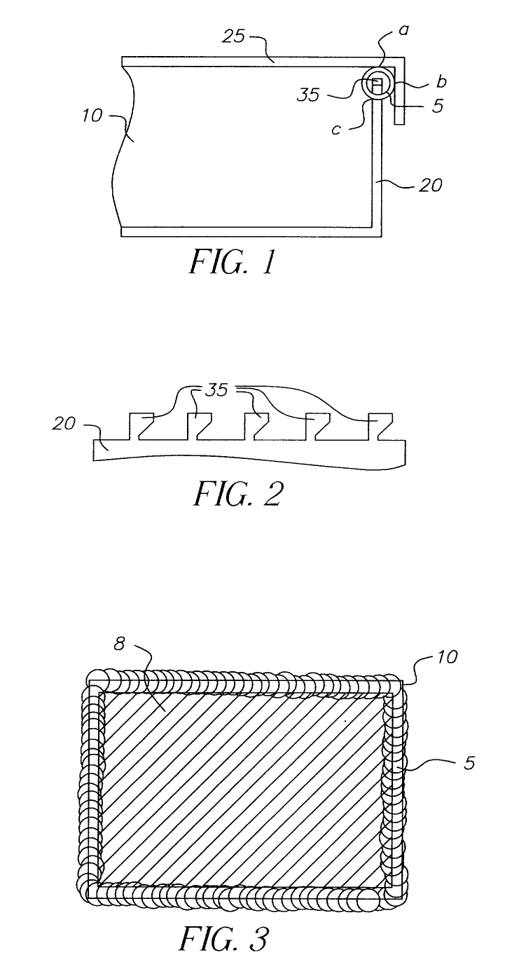

Referring now to the accompanying drawings, FIG. 1 shows a cross-section through a part of an electronic housing 10. The electronic housing 10 includes the housing wall 20 and the housing cover 25. In the electronic housing 10, an electromagnetic radiation source (not shown) is located, which emits electromagnetic radiation. Without precautions, the electromagnetic radiation propagates out of the inner space of the housing 10 through the intermediate spaces between the housing parts 20, 25 to the outside of the housing 10 and acts as perturbing radiation. The problem of the perturbing radiation in electric and electronic devices is indicated by the generic term electromagnetic compatibility (EMC). Between the housing cover 25 and the housing wall 20, an electrically conducting spiral coiled spring 5 is arranged, which essentially includes the intermediate spaces between the housing cover 25 and the housing wall 20 and is shown in the drawing in cross-section. The spiral coiled spring 5 can be extended by exerting force in the axial direction and can be shortened and can act as energy storage for mechanical energy. The spiral coiled spring 5 contacts the housing cover 25 at the contact points a and b and the housing 10 at the contact point c. The spiral coiled spring 5 is held by projections 35 of the housing wall 20. The electromagnetic radiation out of the inner space of the housing 10 is effectively prevented from leaving the housing 10, and acting outside of the housing 10, by the spiral coiled spring 5.

FIG. 2 shows a side view of a section of a housing wall 20, which has projections 35. The projections 35 have a surface perpendicular to the housing wall 20 as a carrier of the projections 35 on the left side according to FIG. 2 as well as an angled surface on the right side, in which the projections 35 taper in the direction of the housing wall 20. In the present example, on the right side of the projections 35 on the housing wall 20 a perpendicular surface is located, which is adjoined by the angled surface, and this surface is adjoined by an additional surface. The upper side of the projections 35 according to FIG. 2 runs approximately parallel to the housing wall 20. The projections 35 can be projections punched from the housing wall 20. In operation, when the spiral coiled spring 5 is mounted on the housing 10, the individual spirals of the spiral coiled spring 5 extend from one projection 35 to the next one. By the described embodiment of the projections 35, the secure mounting of the spiral coiled spring 5 is ensured on the housing wall 20, especially by the described angled surface, to which the spirals of the spiral coiled spring 5 are clamped. A special advantage of the spiral coiled spring 5 is its flexibility crosswise to its lengthwise extension, as shown in FIG. 3. FIG. 3 shows an overhead view of an opened electronic housing 10 with a housing floor 8 in hatched lines and with the spiral coiled spring 5 that is mounted on the housing 10 and is bent at the four corners of the housing 10 and is adapted to the shape of the housing 10. The housing cover 25 according to FIG. 1 is not shown in the diagram according to FIG. 3. The flexible spiral coiled spring 5 can be mounted in a simple manner on the projections 35 such that the spiral coiled spring 5 changes its direction at the corners of the housing 10 in order to shield off the intermediate spaces of the housing parts 20, 25 electromagnetically. In other words, the spiral coiled spring 5 can be adapted to the housing shape. A single suitably adapted spiral coiled spring 5 is sufficient in order to shield off intermediate spaces at any desired length between housing parts 20, 25 electromagnetically. By the flexibility of the spiral coiled spring 5 in any direction, moreover, intermediate spaces between housing parts 20, 25 which do not lie in a plane, as shown in FIG. 3, can be shielded with a single spiral coiled spring 5.

The invention has been described in detail with particular reference to certain preferred embodiments thereof, but it will be understood that variations and modifications can be effected within the spirit and scope of the invention.

What is claimed is:

1. Housing shield for shielding against electromagnetic radiation for intermediate spaces of a housing (10) including housing parts (20, 25), characterized in that an electrically conducting spiral coiled spring (5) is arranged on the intermediate spaces to be shielded, which extends between the housing parts (20, 25).

2. Housing shield for shielding against electromagnetic radiation according to claim 1, characterized in that said spiral coiled spring (5) is a compression spring.

3. Housing shield for shielding against electromagnetic radiation according to claim 1, characterized in that housing walls (20) of said housing (10) have projections (35) for mounting spiral coiled springs (5).

4. Housing shield for shielding against electromagnetic radiation according to claim 1, characterized in that said spiral coiled spring (5) is flexible.
